(19) United States
(12) Patent Application Publication
(10) Pub. No.: US 2025/0089523 A1
(43) Pub. Date: Mar. 13, 2025

(54) DISPLAY DEVICE AND METHOD OF FABRICATING THE SAME

(71) Applicant: Samsung Display Co., LTD., Yongin-si (KR)

(72) Inventors: Joon Ik LEE, Yongin-si (KR); Young Do KIM, Yongin-si, Gyeonggi-do (KR); Jun Woo YOU, Yongin-si (KR); Chang Moo LEE, Yongin-si (KR); Sung Woon IM, Yongin-si (KR)

(73) Assignee: Samsung Display Co., LTD., Yongin-si (KR)

(21) Appl. No.: 18/659,484

(22) Filed: May 9, 2024

(30) Foreign Application Priority Data
Sep. 11, 2023 (KR) 10-2023-0120418

(51) Int. Cl. H10K 59/80; H10K 59/12; H10K 59/40

(52) U.S. Cl. CPC H10K 59/872; H10K 59/1201; H10K 59/40; H10K 59/873; H10K 59/8791

(57) ABSTRACT

The disclosure relates to a display device, and more particularly, to a display device capable of improving an appearance quality and minimizing a light leakage phenomenon, and a method for fabrication thereof. According to an embodiment of the disclosure, a display device comprising: a base substrate; a light emitting element disposed on the base substrate; a protective substrate disposed on the light emitting element; a polarization plate disposed on the protective substrate; and a sidewall disposed on an edge portion of an upper surface of the base substrate.

### CROSS-REFERENCE TO RELATED APPLICATION(S)

This application claims priority to and benefits of Korean Patent Application No. 10-2023-0120418 under 35 U.S.C. § 119, filed on Sep. 11, 2023, in the Korean Intellectual Property Office, the entire contents of which are incorporated herein by reference.

### BACKGROUND

### 1. Technical Field

Embodiments relate to a display device, and more particularly, to a display device capable of improving an appearance quality and minimizing a light leakage phenomenon, and a method for fabrication of the display device.

### 2. Description of the Related Art

Various types of electronic devices, including display modules, are used to provide image information, and electronic devices may include electronic modules that receive external signals or provide output signals to the outside. For example, electronic modules may include camera modules, etc., and the demands for display devices, which obtain high-quality captured images, are increasing.

### SUMMARY

Embodiments provide a display device capable of improving an appearance quality and minimizing a light leakage phenomenon, and a method for fabrication of the display device.

However, embodiments are not limited to those set forth herein. The above and other embodiments will become more apparent to one of ordinary skill in the art to which the disclosure pertains by referencing the detailed description of the disclosure given below.

According to an embodiment of the disclosure, a display device may include: a base substrate; a light emitting element disposed on the base substrate; a protective substrate disposed on the light emitting element; a polarization plate disposed on the protective substrate; and a sidewall disposed on an edge portion of an upper surface of the base substrate.

In an embodiment, the sidewall may extend along the edge portion of the upper surface of the base substrate.

In an embodiment, the sidewall may be further disposed between the side surface of the protective substrate and the side surface of the polarization plate.

In an embodiment, the sidewall may extend along the side surface of the protective substrate and the side surface of the polarization plate.

In an embodiment, the sidewall may surround the protective substrate and the polarization plate.

In an embodiment, the protective substrate may have a smaller size than a size of the base substrate.

In an embodiment, in plan view, the edge portion of the protective substrate may be surrounded by the edge portion of the base substrate.

In an embodiment, the base substrate may have a greater size than a size of the polarization plate.

In an embodiment, in plan view, the edge portion of the base substrate may surround the edge portion of the polarization plate.

In an embodiment, the display device may further include an encapsulation layer disposed on the light emitting element.

In an embodiment, the display device may further include an adhesive layer disposed between the encapsulation layer and the protective substrate.

In an embodiment, the sidewall may be further disposed on the side surface of the adhesive layer.

In an embodiment, the sidewall may extend along the side surface of the adhesive layer.

In an embodiment, the sidewall may surround the adhesive layer.

In an embodiment, the display device may further include a touch sensing unit disposed between the encapsulation layer and the adhesive layer.

In an embodiment, the display device may further include a passivation layer disposed on a lower surface of the base substrate.

In an embodiment, the sidewall may include: a first sidewall portion disposed on the edge portion of the upper surface of the base substrate to cover the side surface of the protective substrate; and a second sidewall portion disposed on the edge portion of the first sidewall portion to cover the side surface of the polarization plate.

In an embodiment, an outer surface of the first sidewall portion may have a linear shape, and an outer surface of the second sidewall portion has a round shape.

In an embodiment, the outer surface of the first sidewall portion and the side surface of the base substrate may be coplanar with each other.

In an embodiment, the first sidewall portion and the second sidewall portion may be integral with each other.

In an embodiment, the sidewall may include a black pigment or an organic black pigment.

According to an embodiment of the disclosure, a method of manufacturing a display device may include: preparing a structure including a base substrate, light emitting elements disposed on the base substrate, and a protective substrate disposed on the light emitting elements; placing a polarization plate on the protective substrate; and placing a sidewall disposed on an edge portion of an upper surface of the base substrate.

In an embodiment, the placing of the sidewall may include: forming a sidewall material disposed on the edge portion of the upper surface of the base substrate; and curing the sidewall material.

In an embodiment, the sidewall may extend along the edge portion of the upper surface of the base substrate.

In an embodiment, the display device may further include placing the sidewall disposed on a side surface of the protective substrate and a side surface of the polarization plate.

In an embodiment, the sidewall may extend along the side surface of the protective substrate and the side surface of the polarization plate.

In an embodiment, the sidewall may surround the protective substrate and the polarization plate.

According to an embodiment, a dead space of a display device may be minimized.

For example, an appearance quality of a display device may be improved.

For example, a light leakage phenomenon of a display device may be minimized.

For example, moisture penetration to the display device may be prevented.

The effects of the disclosure are not limited to the above-described effects and other effects which are not described herein will become apparent to those skilled in the art from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic cross-sectional view taken along line I-I′ of FIG. 1;

FIGS. 3 and 4 are drawings for describing a method of manufacturing a display device according to an embodiment; and

FIG. 5 is a schematic cross-sectional view of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments will be described in detail with reference to the accompanying drawings.

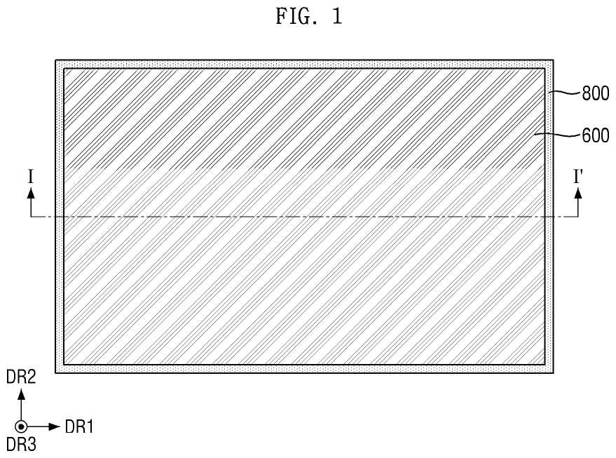

FIG. 1 is a schematic plan view of a display device according to an embodiment, and

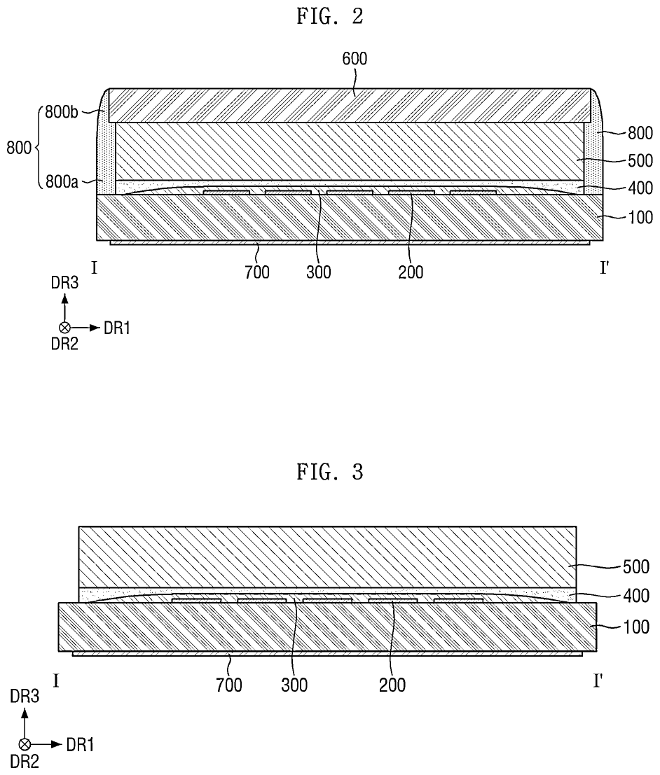

FIG. 2 is a schematic cross-sectional view taken along line I-I′ of FIG. 1.

As illustrated in FIGS. 1 and 2, a display device according to an embodiment may include a passivation layer 700, a base substrate 100, light emitting elements (or display elements) 200, an encapsulation layer 300, an adhesive layer 400, a protective substrate 500, a polarization plate 600, and a sidewall 800.

The passivation layer 700 may perform a light blocking function and protect the lower surface of the base substrate 100. For example, the passivation layer 700 may prevent scratches from occurring on the lower surface of the base substrate 100. For example, the passivation layer 700 may be disposed on the lower surface of the base substrate 100.

The base substrate 100 may be disposed on the passivation layer 700. The base substrate 100 may be a flexible substrate which is bendable, foldable, or rollable. For example, the base substrate 100 may include a polymer resin such as polyimide (PI), but embodiments are not limited thereto. For another example, the base substrate 100 may include a glass material or a metal material. For example, the base substrate 100 may be, for example, an ultra-thin glass. The ultra-thin glass may have, for example, a very thin thickness by an etching process. For example, the thickness may mean a magnitude in a third direction DR3.

The light emitting elements 200 may be disposed on the base substrate 100. For example, the light emitting elements 200 may be disposed on the base substrate 100 in the third direction DR3. For example, the light emitting elements 200 may be disposed on a display area of the base substrate 100. The light emitting elements 200 may include a light emitting element. The light emitting elements may include an anode electrode, a light emitting layer, and a cathode electrode. The anode electrode, the light emitting layer, and the cathode electrode may be sequentially stacked along the third direction DR3. For example, a light emitting layer may be stacked on the anode electrode in the third direction DR3, and a cathode electrode may be disposed on the light emitting layer in the third direction DR3.

The light emitting layer may be an organic light emitting layer including an organic material. The light emitting layer may include a hole transporting layer, an organic light emitting layer, and an electron transporting layer. In case that the anode electrode receives a selected voltage through a thin film transistor and the cathode electrode receives the cathode voltage, holes and electrons may be transferred to the organic light emitting layer through the hole transporting layer and the electron transporting layer, respectively, and may be combined with each other to emit light in the organic light emitting layer.

In another example, the light emitting elements may include a quantum dot light emitting diode including a quantum dot light emitting layer, an inorganic light emitting diode including an inorganic semiconductor, or a micro light emitting diode.

The encapsulation layer 300 may be disposed on the light emitting elements 200. For example, the encapsulation layer 300 may be disposed on the light emitting elements 200 in the third direction DR3. The encapsulation layer 300 may cover the top surface (or upper surface) and the side surfaces of the light emitting elements 200 and protect the light emitting elements 200. The encapsulation layer 300 may include at least one inorganic layer and at least one organic layer for encapsulating the light emitting elements 200.

An adhesive layer 400 may be disposed on the encapsulation layer 300. For example, the adhesive layer 400 may be disposed on the encapsulation layer 300 in the third direction DR3. The adhesive layer 400 may be, for example, an ultraviolet curable adhesive such as an optically clear resin (OCR).

The protective substrate 500 may be disposed on the adhesive layer 400. The protective substrate 500 may be a flexible substrate which is bendable, foldable, or rollable. For example, the protective substrate 500 may include a polymer resin such as polyimide (PI), but embodiments are not limited thereto. For another example, the protective substrate 500 may include a glass material or a metal material.

The protective substrate 500 may overlap the base substrate 100. For example, the entire protective substrate 500 may be overlapped by the base substrate 100. For example, the protective substrate 500 described above may have a smaller area (or smaller size) than the base substrate 100. For example, the area (or size) of the protective substrate 500 along a first direction DRI and a second direction DR2 may be smaller than the area (or size) of the base substrate 100 along the first direction DRI and the second direction DR2. For example, in plan view, the edge portion of the protective substrate 500 may be surrounded by the edge portion of the base substrate 100. For example, the edge portion of the base substrate 100 may extend further in the first direction DRI and the second direction DR2 than the edge portion of the protective substrate 500. Like described above, since the area (or size) of the protective substrate 500 is smaller than the area (or size) of the base substrate 100, dead space of the display device may be minimized.

The polarization plate 600 may be disposed on the protective substrate 500. For example, the polarization plate 600 may be disposed on the protective substrate 500 in the third direction DR3. The polarization plate 600 may include a linear polarization layer and at least one retardation layer. The linear polarization layer may be an optical layer that linearly polarizes light provided from the outside in a direction. The retardation layer may be a λ/2 retardation layer and a λ/4 retardation layer. The polarization plate 600 may function to reduce reflection caused by external light.

The polarization plate 600 may overlap the base substrate 100. For example, the entire polarization plate 600 may be overlapped by the base substrate 100. For example, the base substrate 100 described above may have a greater area (or greater size) than the polarization plate 600. For example, the area (or size) of the base substrate 100 along the first direction DR1 and the second direction DR2 may be greater than the area (or size) of the polarization plate 600 along the first direction DRI and the second direction DR2. For example, in plan view, the edge portion of the base substrate 100 may surround the edge portion of the polarization plate 600. For example, the edge portion of the base substrate 100 may extend further in the first direction DR1 and the second direction DR2 than the edge portion of the polarization plate 600. For example, the polarization plate 600 may overlap the protective substrate 500. For example, the entire protective substrate 500 may be overlapped by the polarization plate 600. For example, the polarization plate 600 described above may have a greater area (or greater size) than the area (or size) of the protective substrate 500. For example, the area (or size) of the polarization plate 600 along the first direction DR1 and the second direction DR2 may be greater than the area (or size) of the protective substrate 500 along the first direction DR1 and the second direction DR2. For example, in plan view, the edge portion of the polarization plate 600 may surround the edge portion of the protective substrate 500. For example, the edge portion of the polarization plate 600 may extend more than the edge portion of the protective substrate 500 in the first direction DRI and the second direction DR2.

For example, a color filter may be further disposed between the protective substrate 500 and the polarization plate 600.

As illustrated in FIG. 1, in plan view, the sidewall 800 may have a closed loop shape surrounding the polarization plate 600. For example, as illustrated in FIGS. 1 and 2, in plan view, the sidewall 800 may have a closed loop shape surrounding the light emitting elements 200, the encapsulation layer 300, the adhesive layer 400, the protective substrate 500 and the polarization plate 600.

As illustrated in FIG. 2, the sidewall 800 may be disposed on the edge portion of the upper surface of the base substrate 100. For example, the sidewall 800 may be disposed on the base substrate 100 in the third direction DR3, and the sidewall 800 may be disposed (or extend) along the edge portion of the upper surface of the base substrate 100. The upper surface of the base substrate 100 may be the surface on which the light emitting elements 200 described above are disposed.

The sidewall 800 may be disposed (or extend) along the edge portion of the upper surface of the base substrate 100. The sidewall 800 may face the edge portion of the upper surface of the base substrate 100 in the third direction DR3. For example, at the edge portion of the upper surface of the base substrate 100, the sidewall 800 may be in contact with the upper surface of the base substrate 100.

The sidewall 800 may be further disposed on the side surface of the adhesive layer 400, the side surface of the protective substrate 500, and the side surface of the polarization plate 600. For example, the sidewall 800 may be disposed on the edge portion of the upper surface of the base substrate 100 described above, along the side surface of the adhesive layer 400, the side surface of the protective substrate 500, and the side surface of the polarization plate 600. For example, the sidewall 800 may be disposed on the edge portion of the upper surface of the base substrate 100 to cover the side surface of the adhesive layer 400, the side surface of the protective substrate 500, and the side surface of the polarization plate 600. The sidewall 800 may face the side surface of the adhesive layer 400, the side surface of the protective substrate 500, and the side surface of the polarization plate 600 in the first direction DRI or the second direction DR2. The sidewall 800 may be in contact with the side surface of the adhesive layer 400, the side surface of the protective substrate 500, and the side surface of the polarization plate 600.

The sidewall 800 may include a light absorbing material. For example, the sidewall 800 may include an inorganic black pigment or an organic black pigment. The inorganic black pigment may be carbon black, and the organic black pigment may include at least one of lactam black, perylene black, or aniline black, but they are not limited thereto. For example, the sidewall 800 may be made of a material including any one of colors other than black.

The sidewall 800 described above may include a first sidewall portion 800a and a second sidewall portion 800b.

The first sidewall portion 800a may be disposed on the edge portion of the upper surface of the base substrate 100. The first sidewall portion 800a may be disposed along the side surface of the adhesive layer 400 and the side surface of the protective substrate 500. For example, the first sidewall portion 800a may be disposed on the edge portion of the upper surface of the base substrate 100 to cover the side surface of the adhesive layer 400 and the side surface of the protective substrate 500. The inner surface of the first sidewall portion 800a may be in contact with the side surface of the adhesive layer 400 and the side surface of the protective substrate 500. The outer surface of the first sidewall portion 800a may have a linear shape or a flat surface. The outer surface of the first sidewall portion 800a may overlap the side surface of the base substrate 100. The outer surface of the first sidewall portion 800a and the side surface of the base substrate 100 may be coplanar with each other, e.g., in the third direction DR3. For example, the outer surface of the first sidewall portion 800a and the side surface of the base substrate 100 may be disposed on an imaginary linear line along the third direction DR3.

The second sidewall portion 800b may be disposed on the first sidewall portion 800a. The second sidewall portion 800b may be disposed along the side surface of the polarization plate 600. For example, the second sidewall portion 800b may be disposed on the first sidewall portion 800a to cover the side surface of the polarization plate 600. The inner surface of the second sidewall portion 800b may be in contact with the side surface of the polarization plate 600. The outer surface of the second sidewall portion 800b may have a round shape, a curved surface, or a convex surface. The second sidewall portion 800b and the first sidewall portion 800a may be integral with each other.

The appearance quality of the display device may be improved by the sidewall 800 described above. For example, the sidewall 800 may planarize steps between the side surface of the base substrate 100, the side surface of the protective substrate 500, and the side surface of the polarization plate 600, thereby improving the appearance quality of the display device. For example, in case that the sidewall 800 is made of a light blocking material, light leakage phenomenon of the display device may be minimized. Further, moisture penetration may be prevented by the sidewall 800.

Hereinafter, a method of manufacturing a display device according to an embodiment will be described with reference to FIGS. 2, 3, and 4 as follows.

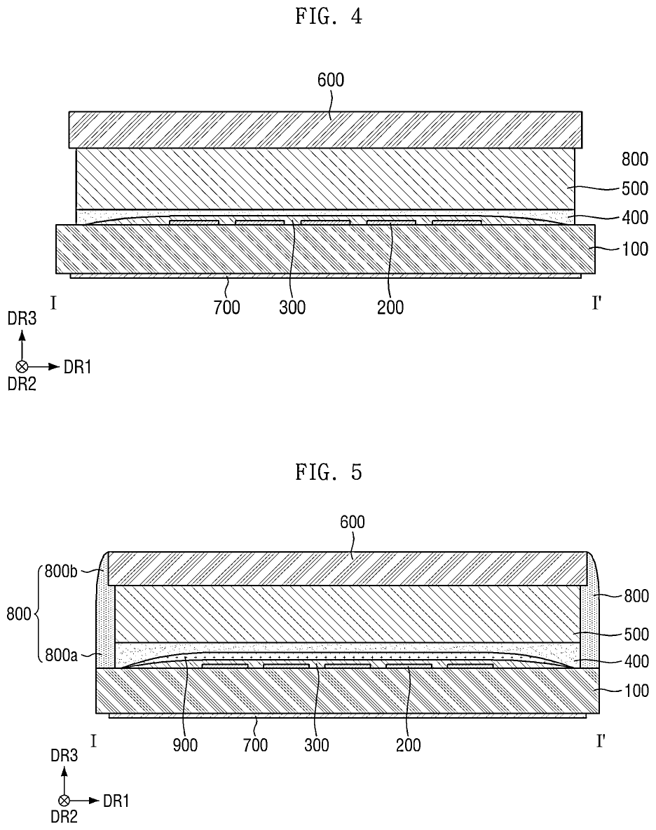

FIGS. 3 and 4 are drawings for describing a method of manufacturing a display device according to an embodiment.

First, as illustrated in FIG. 3, a structure in which a passivation layer 700, a base substrate 100, light emitting elements (or display elements) 200, an encapsulation layer 300, and an adhesive layer 400 may be prepared. For example, a protective substrate 500 may be placed on the adhesive layer 400. The protective substrate 500 may be attached to the adhesive layer 400. In an embodiment, the adhesive layer 400 may be provided to be attached to the lower surface of the protective substrate 500. For example, the protective substrate 500 may include an adhesive layer 400.

Thereafter, as illustrated in FIG. 4, a polarization plate 600 may be disposed on the protective substrate 500. The area (or size) of the polarization plate 600 may be greater than the area (or size) of the protective substrate 500 and smaller than the area (or size) of the base substrate 100. Accordingly, the side surface of the polarization plate 600, the side surface of the protective substrate 500, and the side surface of the base substrate 100 may have steps (or step differences) in the first direction DR1.

Subsequently, as illustrated in FIGS. 1 and 2, a sidewall 800 may be disposed (or extend) along the edge portion of the upper surface of the base substrate 100. For example, the sidewall 800 may be disposed on the edge portion of the upper surface of the base substrate 100 described above, along the side surface of the adhesive layer 400, the side surface of the protective substrate 500, and the side surface of the polarization plate 600.

The sidewall 800 may be formed, for example, by a method of jetting a material (e.g., organic pigment) used for the sidewall 800 using an inkjet equipment. For example, the organic pigment sprayed from a nozzle of the inkjet equipment may be formed along the edge portion of the upper surface of the base substrate 100, the side surface of the adhesive layer 400, the side surface of the protective substrate 500, and the side surface of the polarization plate 600. In an embodiment, the sidewall 800 may be formed, for example, by a method of applying a material used for the sidewall 800 (hereinafter, referred to as a sidewall material; for example, an organic pigment) using inkjet equipment. For example, the organic pigment discharged from the head of the inkjet equipment may be formed along the edge portion of the upper surface of the base substrate 100, the side surface of the adhesive layer 400, the side surface of the protective substrate 500, and the side surface of the polarization plate 600. In an embodiment, the sidewall 800 may be formed by a method of applying a sidewall material (e.g., organic pigment) using electrohydrodynamic (EHD) printing equipment. For example, the organic pigment discharged from the nozzle of the electrohydrodynamic (EHD) printing equipment may be formed along the edge portion of the upper surface of the base substrate 100, the side surface of the encapsulation layer 300, the side surface of the protective substrate 500, and the side surface of the polarization plate 600.

For example, the organic pigment formed along the edge portion of the upper surface of the base substrate 100, the side surface of the encapsulation layer 300, the side surface of the protective substrate 500, and the side surface of the polarization plate 600 may be cured by a curing process. The curing process may include, for example, at least one of an ultraviolet curing process, a heat curing process, and a room temperature curing process. For example, the organic pigment may be cured by applying ultraviolet rays or heat to the organic pigment. In another example, organic pigments may be naturally cured by being left at room temperature for a certain period of time. The cured organic pigment may function as the sidewall 800. The sidewall 800 may planarize the steps (or step differences) between the side surface of the base substrate 100, the side surface of the protective substrate 500, and the side surface of the polarization plate 600, thereby improving the appearance quality of the display device.

FIG. 5 is a schematic cross-sectional view of a display device according to an embodiment, and may be a schematic cross-sectional view taken along line I-I′ of FIG. 1.

The display device of FIG. 5 is different from the display device of FIG. 2 in further including a touch sensing unit 900, and the difference will be mainly described as the followings.

The touch sensing unit 900 may be disposed on the encapsulation layer 300. For example, the touch sensing unit 900 may be disposed between the encapsulation layer 300 and the adhesive layer 400. The touch sensing unit 900 may include touch electrodes for sensing a user's touch in a capacitive manner, and touch lines connecting the touch electrodes to the touch driver. For example, the touch sensing unit 900 may sense the user's touch by using a mutual capacitance method or a self-capacitance method.

For another example, the touch sensing unit 900 may be disposed on a separate substrate disposed on a display area of the display device. For example, the substrate supporting the touch sensing unit 900 may be a base member that encapsulates the display area.

The touch electrodes of the touch sensing unit 900 may be disposed in a touch sensor area overlapping the display area of the display device. The touch lines of the touch sensing unit 900 may be disposed in a touch peripheral area that overlaps a non-display area of the display device.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a base substrate;
a light emitting element disposed on the base substrate;
a protective substrate disposed on the light emitting element;
a polarization plate disposed on the protective substrate; and
a sidewall disposed on an edge portion of an upper surface of the base substrate.

2. The display device of claim 1, wherein the sidewall extends along the edge portion of the upper surface of the base substrate.

3. The display device of claim 1, wherein the sidewall is further disposed between a side surface of the protective substrate and a side surface of the polarization plate.

4. The display device of claim 1, wherein the sidewall extends along a side surface of the protective substrate and a side surface of the polarization plate.

5. The display device of claim 4, wherein the sidewall surrounds the protective substrate and the polarization plate.

6. The display device of claim 1, wherein the protective substrate has a smaller size than a size of the base substrate.

7. The display device of claim 6, wherein, in plan view, the edge portion of the protective substrate is surrounded by the edge portion of the base substrate.

8. The display device of claim 1, wherein the base substrate has a greater size than a size of the polarization plate.

9. The display device of claim 8, wherein, in plan view, the edge portion of the base substrate surrounds the edge portion of the polarization plate.

10. The display device of claim 1, further comprising:
an encapsulation layer disposed on the light emitting element.

11. The display device of claim 10, further comprising:
an adhesive layer disposed between the encapsulation layer and the protective substrate.

12. The display device of claim 11, wherein the sidewall is further disposed on a side surface of the adhesive layer.

13. The display device of claim 12, wherein the sidewall extends along the side surface of the adhesive layer.

14. The display device of claim 13, wherein the sidewall surrounds the adhesive layer.

15. The display device of claim 11, further comprising:
a touch sensing unit disposed between the encapsulation layer and the adhesive layer.

16. The display device of claim 1, further comprising:
a passivation layer disposed on a lower surface of the base substrate.

17. The display device of claim 1, wherein the sidewall comprises:
a first sidewall portion disposed on an edge portion of an upper surface of the base substrate to cover a side surface of the protective substrate; and
a second sidewall portion disposed on the edge portion of the first sidewall portion to cover the side surface of the polarization plate.

18. The display device of claim 17, wherein
an outer surface of the first sidewall portion has a linear shape, and
an outer surface of the second sidewall portion has a round shape.

19. The display device of claim 18, wherein the outer surface of the first sidewall portion and the side surface of the base substrate are coplanar with each other.

20. The display device of claim 17, wherein the first sidewall portion and the second sidewall portion are integral with each other.

21. The display device of claim 1, wherein the sidewall includes a black pigment or an organic black pigment.

22. A method of manufacturing a display device, the method comprising:
preparing a structure including a base substrate, light emitting elements disposed on the base substrate, and a protective substrate on the light emitting elements;
placing a polarization plate on the protective substrate; and
placing a sidewall disposed on an edge portion of an upper surface of the base substrate.

23. The method of claim 22, wherein the placing of the sidewall comprises:
forming a sidewall material on the edge portion of the upper surface of the base substrate; and
curing the sidewall material.

24. The method of claim 22, wherein the sidewall extends along the edge portion of the upper surface of the base substrate.

25. The method of claim 22, further comprising:
placing the sidewall disposed on a side surface of the protective substrate and a side surface of the polarization plate.

26. The method of claim 25, wherein the sidewall extends along the side surface of the protective substrate and the side surface of the polarization plate.

27. The method of claim 26, wherein the sidewall surrounds the protective substrate and the polarization plate.
